(19) United States
(12) Patent Application Publication
(10) Pub. No.: US 2009/0079465 A1
(43) Pub. Date: Mar. 26, 2009

(54) SEMICONDUCTOR INTEGRATED CIRCUIT

(76) Inventors: Toshio Sasaki, Tokyo (JP); Yoshihiko Yasu, Tokyo (JP); Ryo Mori, Tokyo (JP); Koichiro Ishibashi, Tokyo (JP); Yusuke Kanno, Kodaira (JP)

Correspondence Address: MILES & STOCKBRIDGE PC, 1751 PINNACLE DRIVE, SUITE 500, MCLEAN, VA, 22102-3833, US

(21) Appl. No.: 11/912,272

(22) PCT Filed: Apr. 21, 2005
(86) PCT No.: PCT/JP2005/007596

§ 371 Date: Oct. 22, 2007

(51) Int. Cl. H03K 17/16

(52) U.S. Cl. 326/21

(57) ABSTRACT

The present invention aims to make each power shutdown area appropriate.

Cell areas each comprising a plurality of core cells arranged therein, and power switches disposed corresponding to the respective cell areas are provided. A plurality of power shutdown areas are respectively formed in units of the core cells. In each power shutdown area, power shutdown is enabled by the power switches corresponding to the power shutdown areas. Thus, the power shutdown areas can be set finely in the core cell units, and the appropriateness of each power shutdown area is achieved. With its appropriateness, a reduction in current consumption at standby is achieved.

### TECHNICAL FIELD

The present invention relates to a layout technology of a semiconductor integrated circuit, and particularly to a technology effective if applied to a semiconductor integrated circuit in which a number of minimum cells (hereinafter described as core cells) constituted of transistors and logic gates are coupled thereby to form functional modules having predetermined functions.

### BACKGROUND ART

A typical method for reducing power consumption at the time when each of functional modules in a semiconductor integrated circuit is kept in a standby state, is to stop a clock supplied to the inside of each functional module. When, however, leak current at the turning off of a transistor is large, the effect of reducing power consumption is not enough even though the supply of the clock to the inside of the functional module kept in the standby state is stopped. As a semiconductor integrated circuit capable of cutting off leakage current flowing through an unused circuit block and achieving a reduction in power consumption as has been described in, for example, a patent document 1, there has been known a technology wherein power shutdown means are provided for cutting off connecting portions between first power main lines and second power main lines when a shutoff command is outputted, and a circuit configuration of the power shutdown means is configured equivalently to one in which a plurality of switching elements are arranged in parallel.

As has been described in, for example, a patent document 2 as a technology for cutting off a power supply voltage for some circuits to reduce power consumption while preventing a circuit's malfunction and an increase in circuit area, there has been known one which divides the inside of a chip into a plurality of circuit blocks and is configured so as to make it possible to cut off the supply of a power supply voltage to any of the circuit blocks and which is provided with block-to-block interface circuits at positions before the branching of a signal being done.

Further, when the supply of power to each functional module is cut off, it reaches a floating state on a voltage basis. Therefore, an input gate of power shutdown-free functional module with the signal being used as an input is brought into floating, thus resulting in the occurrence of leakage current in the input gate. As has been described in, for example, a patent document 3 as its measures, a voltage fixing circuit is provided between an output terminal of each power shut-down functional module and an input terminal of each power shutdown-free functional module. Upon power shutdown, the voltage fixing circuit may fix a signal voltage supplied to the functional module to a ground level to avoid that the input gate of the power shutdown-free functional module is brought into floating.

[Patent Document 1] Japanese Patent Laid-Open No. Hei 10 (1998)-200050 (FIG. 11)

### [Patent Document 2] Japanese Patent Laid-Open No. 2003-92359 (FIG. 1)

### [Patent Document 3] Japanese Patent Laid-Open No. 2003-215214 (FIG. 4)

### DISCLOSURE OF THE INVENTION

### Problems that the Invention is to Solve

The present inventors have examined power shutdown of a semiconductor integrated circuit. According to it, the present inventors have found out that in the related art, a certain amount of gate scales are combined into a functional module, which is used as the unit of power shutdown, and when each power shutdown area is set in its unit, the division of power areas is made impossible after the layout thereof. That is, the floor plan of a semiconductor chip is decided in advance and each functional module to be power shut-down is determined to set the corresponding power shutdown area. From this regard, resetting of shutdown blocks such as changes in subsequent shutdown area size, logic area to be cut off and the like cannot be re-created from relations with peripheral blocks. It was therefore become difficult to make each power shutdown area appropriate in the semiconductor integrated circuit.

An object of the present invention is to provide a technology for making a power shutdown area appropriate.

The above, other objects and novel features of the present invention will become apparent from the description of the present specification and the accompanying drawings.

### Means for Solving the Problems

Summaries of representative ones of the inventions disclosed in the present application will be explained briefly as follows:

[1] There is provided a first invention wherein cell areas each comprising a plurality of core cells arranged therein and power switches disposed corresponding to the respective cell areas are provided, a plurality of power shutdown areas are respectively formed in units of the core cells, and in the respective power shutdown areas, power shutdown is enabled by the power switches corresponding to the power shutdown areas.

According to the above means, since the power shutdown areas can be set finely in the core cell units, the power shutdown areas can be made appropriate. With their appropriateness, current consumption at standby can be reduced.

[2] In the above [1], first low-potential side power lines each provided as a ground line, and second low-potential side power lines coupled to the core cells respectively are provided. The power switches are provided so as to be capable of interrupting the first low-potential side power lines and the second low-potential side power lines.

[3] In the above [2], a plurality of power shutdown areas can be provided by dividing the second low-potential side power lines.

[4] In the above [3], the power switches are provided as MOS transistors whose gate sizes are determined depending upon the areas of the power shutdown areas corresponding to the power switches.

[5] In the above [4], comparison circuits for comparing identification information set in the respective power shutdown areas with comparison input information inputted thereto are provided. The operation of each of the power switches can be controlled based on the result of comparison by the comparison circuit.

[6] There is provided a second invention comprising cell areas each comprising a plurality of core cells arranged therein, power switches disposed corresponding to the respective cell areas, metal upper layer lines respectively coupled to the power switches, and metal lower layer lines which respectively intersect with the metal upper layer lines and are respectively coupled to the metal upper layer lines at points of intersection thereof. The cell areas are divided into a plurality of power shutdown areas in units of the core cells respectively. The metal lower layer lines are divided corresponding to the division of the power shutdown areas. Hence, in the respective power shutdown areas, power shutdown is enabled by the power switches corresponding to the power shutdown areas.

[7] In the above [6], first low-potential side power lines each provided as a ground line are provided. The power switches include MOS transistors provided so as to be capable of interrupting the first low-potential side power lines and the metal upper layer lines.

[8] In the above [7], MOS transistors disposed on both end sides of the metal upper layer lines can be contained in the power switches.

[9] In the above [8], first MOS transistors capable of electrically dividing the metal upper layer lines, and second MOS transistors capable of electrically dividing the metal lower layer lines can be contained in the power switches.

[10] In the above [6], third MOS transistors respectively provided at one ends of the metal upper layer lines, and fourth MOS transistors respectively provided at intermediate portions of the metal upper layer lines can be contained in the power switches.

### EFFECT OF THE INVENTION

An advantageous effect obtained by a representative one of the inventions disclosed in the present application will be explained briefly as follows.

There can be provided a semiconductor integrated circuit that has made each power shutdown area appropriate.

### BRIEF DESCRIPTION OF THE DRAWINGS

FIG. 1 is a layout explanatory diagram of a principal part of a semiconductor integrated circuit according to the present invention.

FIG. 2 is another layout explanatory diagram of the principal part of the semiconductor integrated circuit.

FIG. 3 is a further layout explanatory diagram of the principal part of the semiconductor integrated circuit.

FIG. 4 is a still further layout explanatory diagram of the principal part of the semiconductor integrated circuit.

FIG. 5 is a circuit diagram showing a configuration example of the principal part shown in FIG. 4.

FIG. 6 is a circuit diagram showing a configuration example of the principal part shown in FIG. 4.

FIG. 7 is a still further layout explanatory diagram of the principal part of the semiconductor integrated circuit.

FIG. 8 is a still further layout explanatory diagram of the principal part of the semiconductor integrated circuit.

FIG. 9 is a still further layout explanatory diagram of the principal part of the semiconductor integrated circuit.

FIG. 10 is a still further layout explanatory diagram of the principal part of the semiconductor integrated circuit.

FIG. 11 is a still further layout explanatory diagram of the principal part of the semiconductor integrated circuit.

FIG. 12 is a still further layout explanatory diagram of the principal part of the semiconductor integrated circuit.

FIG. 13 is a still further layout explanatory diagram of the principal part of the semiconductor integrated circuit.

FIG. 14 is a still further layout explanatory diagram of the principal part of the semiconductor integrated circuit.

FIG. 15 is a still further layout explanatory diagram of the principal part of the semiconductor integrated circuit.

FIG. 16 is a still further layout explanatory diagram of the principal part of the semiconductor integrated circuit.

FIG. 17 is a still further layout explanatory diagram of the principal part of the semiconductor integrated circuit.

FIG. 18 is a still further layout explanatory diagram of the principal part of the semiconductor integrated circuit.

FIG. 19 is a still further layout explanatory diagram of the principal part of the semiconductor integrated circuit.

FIG. 20 is a still further layout explanatory diagram of the principal part of the semiconductor integrated circuit.

FIG. 21 is an operation timing diagram of the principal part in the circuit shown in FIG. 20.

FIG. 22 is a still further layout explanatory diagram of the principal part of the semiconductor integrated circuit.

FIG. 23 is a still further layout explanatory diagram of the principal part of the semiconductor integrated circuit.

### EXPLANATION OF REFERENCE NUMERALS

100 semiconductor integrated circuit
201-204 and 221-224 power switch circuits
305-308, 312, 313, 703, 731-734 and 751-754 power switches
VDD high-potential side power supply
VSS first low-potential side power supply
VSSM second low-potential side power supply
A, B, C power shutdown areas
701 metal lower layer line
702, 831 and 832 metal upper layer lines

### BEST MODE FOR CARRYING OUT THE INVENTION

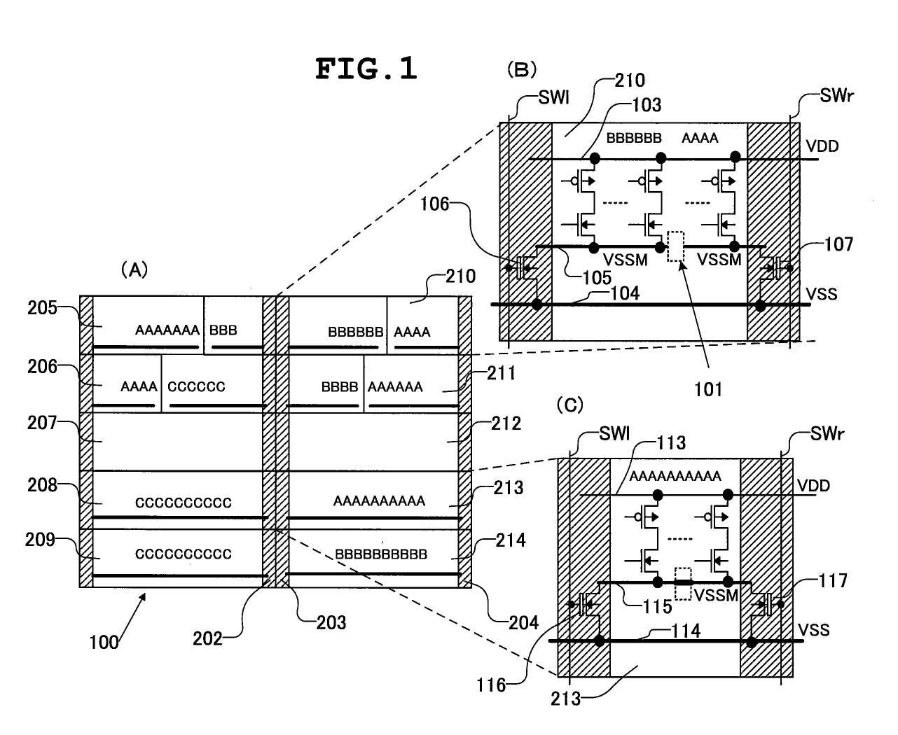

A configuration example of a semiconductor integrated circuit according to the present invention is shown in FIG. 1(A).

Although not restricted in particular, the semiconductor integrated circuit 100 shown in FIG. 1(A) is configured as a microcomputer formed in one semiconductor substrate such as a monocrystal silicon substrate by the known semiconductor integrated circuit manufacturing technology. The semiconductor integrated circuit 100 includes a plurality of cell areas 205 through 214, and power switch circuits 201 through 204 capable of cutting off the supply of power to the cell areas 205 through 214. The power switch circuits are respectively disposed on both sides of the cell areas 205 through 214. In the cell areas 205 through 214, A through F indicate power shutdown groups. The power shutdown groups A through F enable the cut-off of the supply of power by means of their corresponding power switch circuits 201 through 204. When different power shutdown groups are formed within one of the cell areas 205 through 214, power supply lines are divided every power shutdown group.

A principal part shown in FIG. 1(A) is shown in FIGS. 1(B) and 1(C) in enlarged form.

As shown in FIG. 1(B) and FIG. 1(C), a high-potential side power VDD line 103, a first low-potential side power VSS line 104, and a second low-potential side power VSSM line 105, which are used to supply power to a logic circuit, are formed in the cell areas 210 and 213. The high-potential side power VDD line 103 enables the supply of a high-potential side power supply VDD. The first low-potential side power VSS line 104 and the second low-potential side power VSSM line 105 enable the supply of a low-potential side power supply VSS. Here, the second low-potential side power VSSM line 105 is coupled to the first low-potential side power supply VSS through n channel type MOS transistors 106 and 107. The n channel type MOS transistor 106 is capable of performing operational control by a control signal SW1, and the n channel type MOS transistor 107 is capable of performing operational control by a control signal SWr. The first low-potential side power VSS line 104 is provided as a common ground line. For example, the power shutdown group A and the power shutdown group B are formed in the cell area 210. In order to enable the individual shutoff of power from the power shutdown group A and the power shutdown group B, the second low-potential side power VSSM line 105 is divided in mid course as designated at 101. The control signals SW1 and SWr are of signals formed by a power controller or the like not shown in the semiconductor integrated circuit 100. When the control signal SW1 is brought to a low level so that the n channel type MOS transistor 106 is brought to an off state upon a standby state, for example, the supply of power to the power shutdown group B is cut off. When the control signal SWr is rendered low in level so that the n channel type MOS transistor 107 is brought to an off state, the supply of power to the power shutdown group A is cut off. When one in which a p channel type MOS transistor and an n channel type MOS transistor are connected in series is configured as a minimum cell (core cell) for a logic gate, the power shutdown groups can be adjusted in units of core cells depending upon at which portion the second low-potential side power VSSM line 105 is divided.

On the other hand, though a high-potential side power VDD line 113, a first low-potential side power VSS line 114 and a second low-potential side power VSSM line 115 are provided in the cell area 213 as shown in FIG. 1(C), only the power shutdown group A is formed in the cell area 213 and the second low-potential side power VSSM line 115 is not divided in mid course. Since, in this case, the supply of power to the power shutdown group A cannot be cut off unless both n channel type MOS transistors 116 and 117 are respectively brought to an off state, the control signals SW1 and SW2 are normally made equal in logic to each other. That is, the n channel type MOS transistors 116 and 117 are on/off-controlled simultaneously by the power controller or the like.

Incidentally, other cell areas are also configured in a manner similar to the cell areas 210 and 213.

The above formation of power shutdown groups is performed at the layout of the semiconductor integrated circuit 100. The layout of the semiconductor integrated circuit 100 is performed in the following manner by a DA (Design Automation) tool.

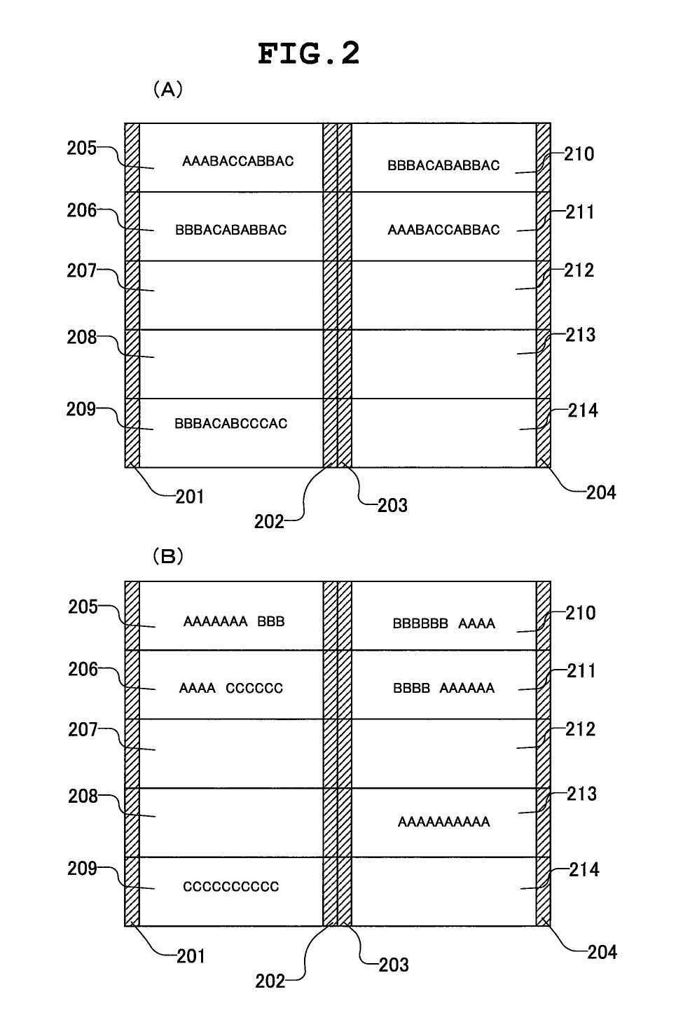

As shown in FIG. 2(A), an automatic layout wiring process is first performed without regard for the power shutdown groups in a state in which logic cells having different power attributes are existent in mixed form (Step S1). Next, as shown in FIG. 2(B), the logic cells are relocated with being divided into at least two types of power attributes, depending upon the power attributes (Step S2). By relocating the logic cells with being divided into, for example, a power attribute that belongs to A and a power attribute that belongs to B, a power shutdown group (called “power shutdown group A” for convenience) having the power attribute belonging to A, and a power shutdown group (called “power shutdown group B”) having the power attribute belonging to B are formed. After their relocation, the second low-potential side power VSSM line 105 is divided according to the above division as shown in FIG. 1(B) (Step S3).

Incidentally, the second low-potential side power VSSM line 105 is divided into core cell units from the beginning, and the second low-potential side power VSSM lines 105 may be coupled with respect to every logic cell that belongs to each power attribute.

According to the above example, the following operative effects can be obtained.

(1) The semiconductor integrated circuit 100 is subdivided in core cell units, and the power shutdown group can be set finely in the core cell units. It is therefore possible to make the power shutdown areas appropriate. With their appropriateness, current consumption at standby can be reduced. Even when a power shutdown area size and a logic area to be cut off appear, they can be handled flexibly. It is thus possible to make the power shutdown areas appropriate.

(2) Since it is possible to make power shutdown at standby appropriate by the operative effects of (1), a reduction in power consumption can be achieved by eliminating at-standby wasted current at the semiconductor integrated circuit.

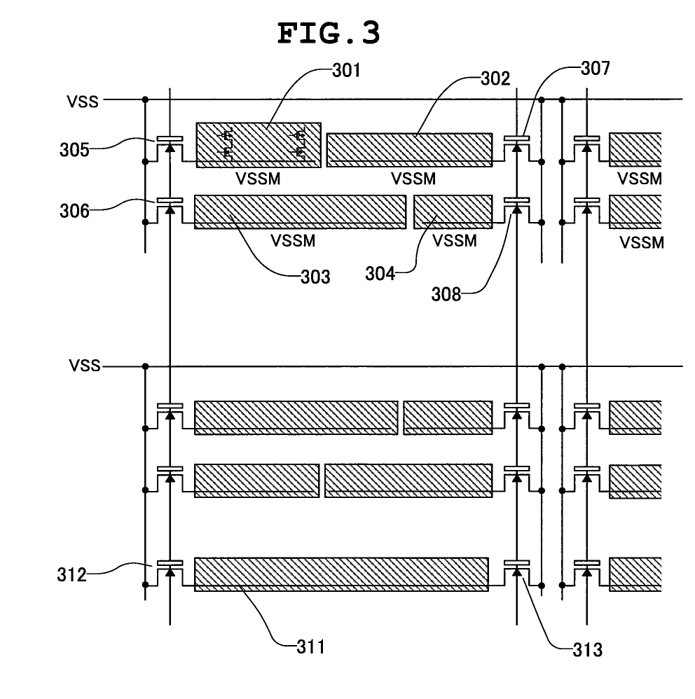

Another configuration example of the principal part of the semiconductor integrated circuit according to the present invention is shown in FIG. 3.

Upon the division of the second low-potential side power VSSM line based on each relocating wiring at Step S3 referred to above, each space cell at which a line has been divided in advance may be disposed where a line to be divided originally is connected by an arrangement of each logic cell. It is necessary to determine a gate size (gate width/gate length) of each power switch in such a manner that the level of the second low-potential side power VSSM line can be set to a ground level within a predetermined time. Now consider that core rows 301, 302, 303 and 304 are formed by relocating wirings as shown in FIG. 3, for example. Since the core rows 301, 302, 303 and 304 are respectively formed by arranging a plurality of core cells and equal to the power shutdown groups shown in FIGS. 1 and 2. The core row 303 is largest in its exclusively-possessed area and the core row 304 is smallest in its exclusively-possessed area. Each of the exclusively-possessed areas of the core rows 301 and 302 is an intermediate size made between the core row 303 and the core row 304. In such a case, a power switch 306 for the core row 303 is largest in terms of the gate size of a MOS transistor, whereas a power switch 308 for the core row 304 is smallest in terms of the gate size thereof. A power switch 305 for the core row 301 and a power switch 307 for the core row 302 are an intermediate size made between the power switch 306 and the power switch 308. Incidentally, since the supply of power is done from both sides of a core row 311 via power switches 312 and 313 where a core row free of division of a second low-potential side power VSSM line is taken as in the case of the core row 311, a relatively small gate size is enough for the power switches 312 and 313.

The control signals SW1 and SWr and the like for driving the power switches can be generated as follows:

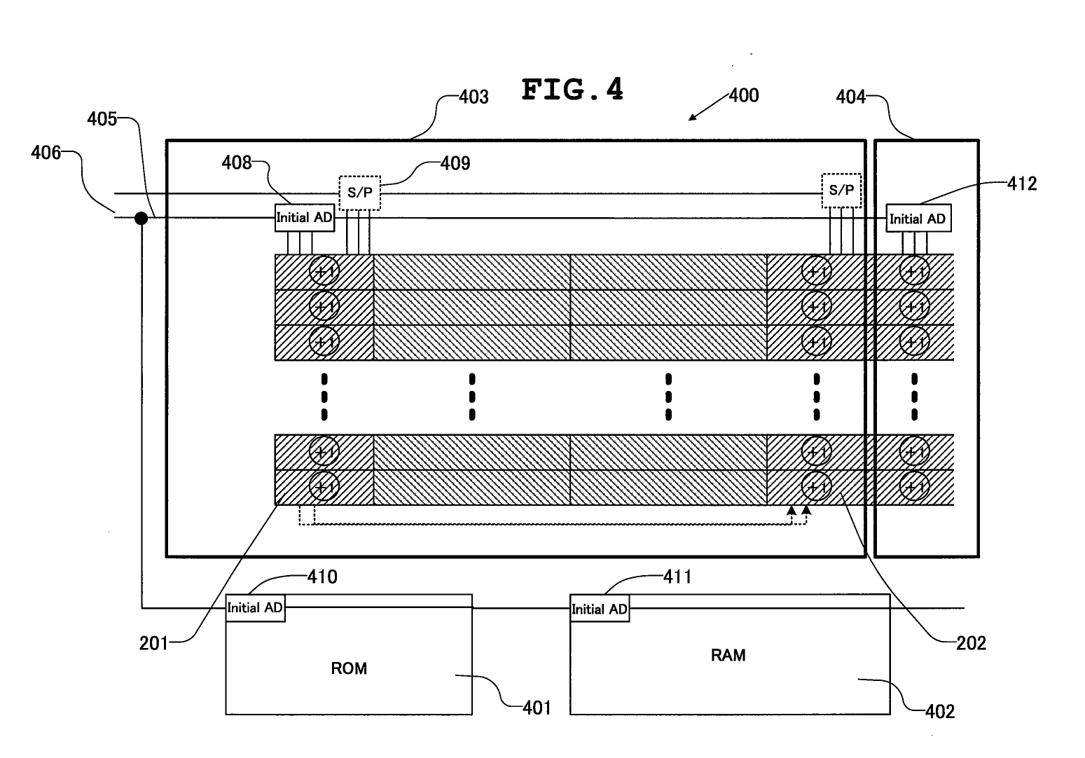

Although not restricted in particular, the semiconductor integrated circuit 400 shown in FIG. 4 is configured as a microcomputer formed in one semiconductor substrate such as a monocrystal silicon substrate by the known semiconductor integrated circuit manufacturing technology. The semiconductor integrated circuit 400 includes functional modules 401, 402, 403 and 404 which respectively fulfill predetermined functions. Since circuits that generate the control signals SW1 and SWr and the like for driving the power switches are basically identical in configuration to the functional modules 401, 402, 403 and 404, the internal configuration of only the functional module 403 is shown in FIG. 4. Although not restricted in particular, the functional module 401 is configured as a ROM (Read Only Memory), the functional module 402 is configured as a RAM (Random Access Memory), and the functional modules 403 and 404 are configured as external interfaces respectively. Initial registers (initial ADs) 410, 411, 408 and 412 are respectively provided within the functional modules 401, 402, 403 and 404. Although not restricted in particular, the initial registers 410, 411, 408 and 412 respectively assume a 3-bit configuration and their initial values are set by a register set signal 405 supplied from an unillustrated CPU or the like. When it is not necessary to change the initial values, the logics of respective bits at the initial registers 410, 411, 408 and 412 may be fixed on a direct-current basis. In the functional module 403, a signal outputted from the initial register 408 is supplied to power switch circuits 201 and 202. A serial-parallel converter 409 for converting data 406 for comparison inputted in serial form into parallel form is provided within each of the functional modules 401, 402, 403 and 404. A signal outputted from the serial-parallel converter 409 is supplied to each of the power switch circuits 201 and 202. Incidentally, if the power switch circuits 201 and 202 are turned on in order little by little by an increment in the comparison data 406 or the like, then inrush current can be reduced by suppressing the number of power switches turned on simultaneously.

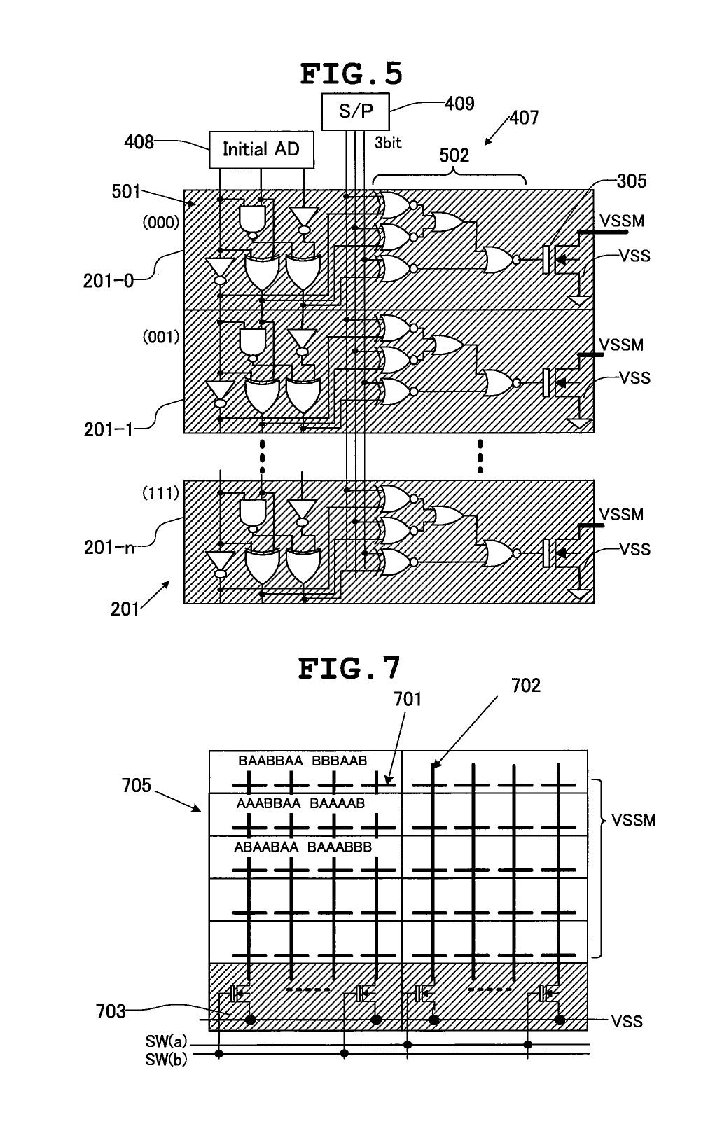

A configuration example of the power switch circuit 201 is shown in FIG. 5.

The power switch circuit 201 includes a plurality of section circuits 201-0, 201-1, . . . , and 201-n. Since the selection circuits 201-0, 201-1, . . . , and 201-n are identical in configuration to one another, only the selection circuit 201-0 will be described in detail. The selection circuit 201-0 includes an arithmetic counter 501 for incrementing input data (by +1), a comparison circuit 502 for comparing the output logic of the arithmetic counter 501 with the output logic of the serial-parallel converter 409, and an n channel type MOS transistor (power switch) 305 driven and controlled by a signal outputted from the comparison circuit 502. The arithmetic counter 501 is formed by a combination of a two-input NAND gate, inverters and exclusive OR gates. The comparison circuit 502 is formed by a combination of exclusive OR gates, an OR gate and a NOR gate. When a logic value “000” is applied to the arithmetic counter 201-0 by the initial registers 408, a logic value “001” is applied to its corresponding arithmetic counter lying within the selection circuit 201-1, and a logic value “111” is applied to its corresponding arithmetic counter lying within the section circuit 201-n. Here, the outputs of the arithmetic counters 501 at the selection circuits 201-0, 201-1, . . . , and 201-n are used as identification information of respective power shutdown areas referred to above. Each of the comparison circuits 502 lying within the selection circuits 201-0, 201-1, . . . , and 201-n compares the output logic of the arithmetic counter 501 with the output logic of the serial-parallel converter 409. When the output logic of the arithmetic counter 501 and the output logic of the serial-parallel converter 409 coincide with each other upon the above comparison, the n channel type MOS transistor 305 corresponding thereto is brought into conduction, so that a first low-potential side power VSS line and a second low-potential side power VSSM line are coupled to each other.

Thus, since the output logic of the arithmetic counter 501 and the output logic of the serial-parallel converter 409 are compared with each other by each of the comparison circuits 502 lying within the selection circuits 201-0, 201-1, . . . , and 201-n and the operation of the corresponding n channel type MOS transistor 305 is controlled based on the result of comparison, power shutdown can selectively be performed on core rows at which power is to be shut down. Further, since the register set signal 405 and the data 406 for comparison are supplied to each functional module in serial form, an increase in the number of wirings between the functional blocks can be suppressed.

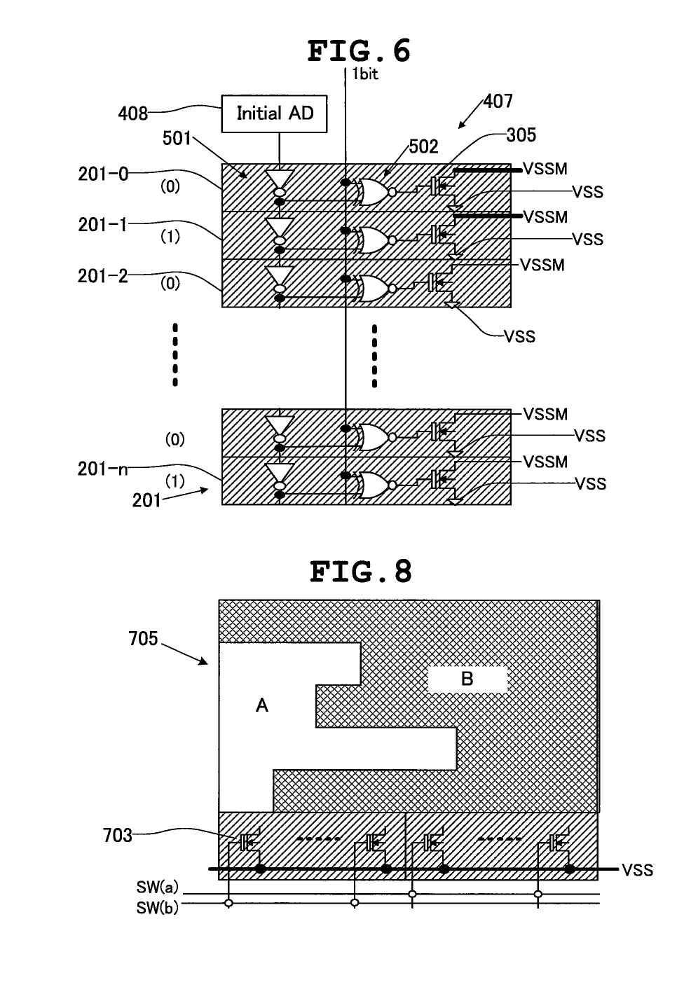

FIG. 6 shows a case in which a plurality of selection circuits 201-0, 201-1, . . . , and 201-n have one-bit configurations respectively. In this case, an arithmetic counter 501 is formed by one inverter, and a comparison circuit 502 is formed by one exclusive OR gate. When each of the selection circuits 201-0, 201-1, . . . , and 201-n has the one-bit configuration, its corresponding initial register 408 also assumes a one-bit configuration. In the case of the one-bit configuration, no serial-parallel converter is required.

Although the power switch circuits are provided on both sides of each cell area in the above example, the power switch circuits can be provided at positions different therefrom. In a cell area 705 as shown in FIG. 7 by way of example, a second low-potential side power VSSM line is formed in such a manner that metal lower layer lines 701 and metal upper layer lines 702 intersect one another. Consider where the metal lower layer lines 701 and the metal upper layer lines 702 are coupled to one another by contacts, and power switches 703 are provided to respective metal upper layer lines 702. In FIG. 7, a power shutdown group A and a power shutdown group B are not yet divided.

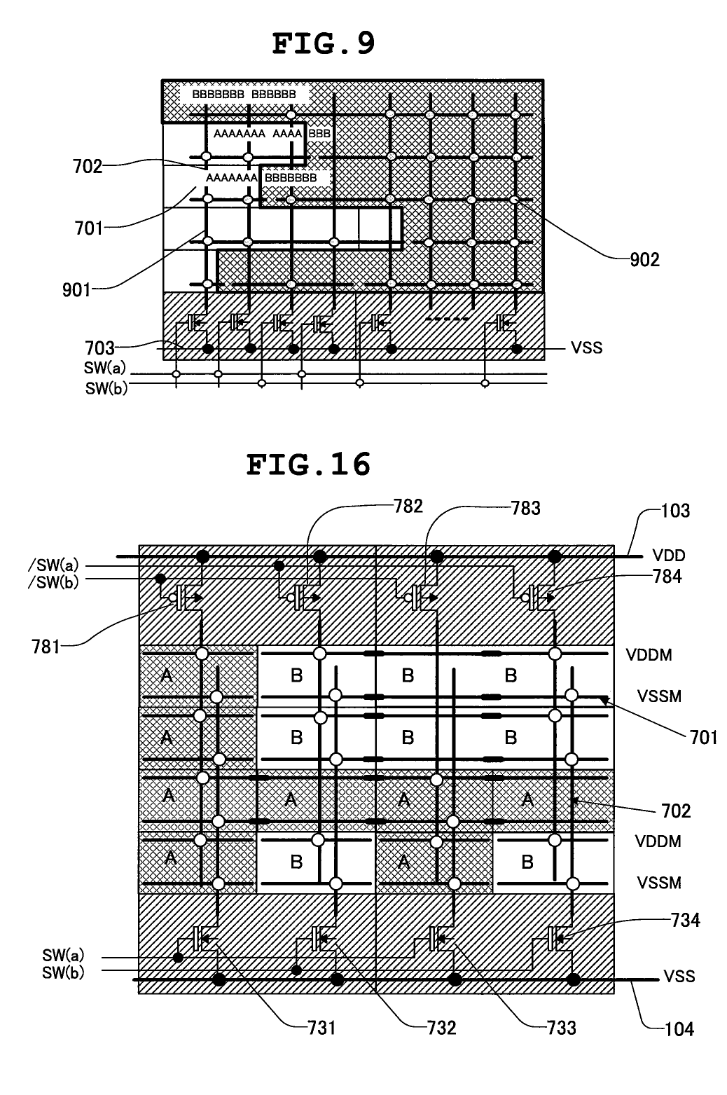

Next, as shown in FIG. 8, the power shutdown group A and the power shutdown group B are divided in core cell units by relocating wiring. The metal lower layer line 701 is divided in association with this division. That is, the metal lower layer line 701 is divided into lines that belong to the power shutdown group A and lines that belong to the power shutdown group B. As shown in FIG. 9, the power switches 703 are arranged every metal upper layer line 702. The metal upper layer lines 702 coupled to the power switches 703 operation-controlled by a control signal SW(a) are coupled to one another by their corresponding metal lower layer lines 701 and contacts 901 in the power shutdown group A. The metal upper layer lines 702 coupled to the power switches 703 operation-controlled by a control signal SW(b) are coupled to one another by their corresponding metal lower layer lines 701 and contacts 902 in the power shutdown group A. Selectively disconnecting the power shutdown groups A and B from the low-potential side power VSS line by the control signals SW(a) and SW(b) enable the cut-off of the supply of power to the power shutdown groups A and B. At the power switches 703, the thickness of a gate oxide film may be decided in consideration of inrush current, leakage current of each channel and the like.

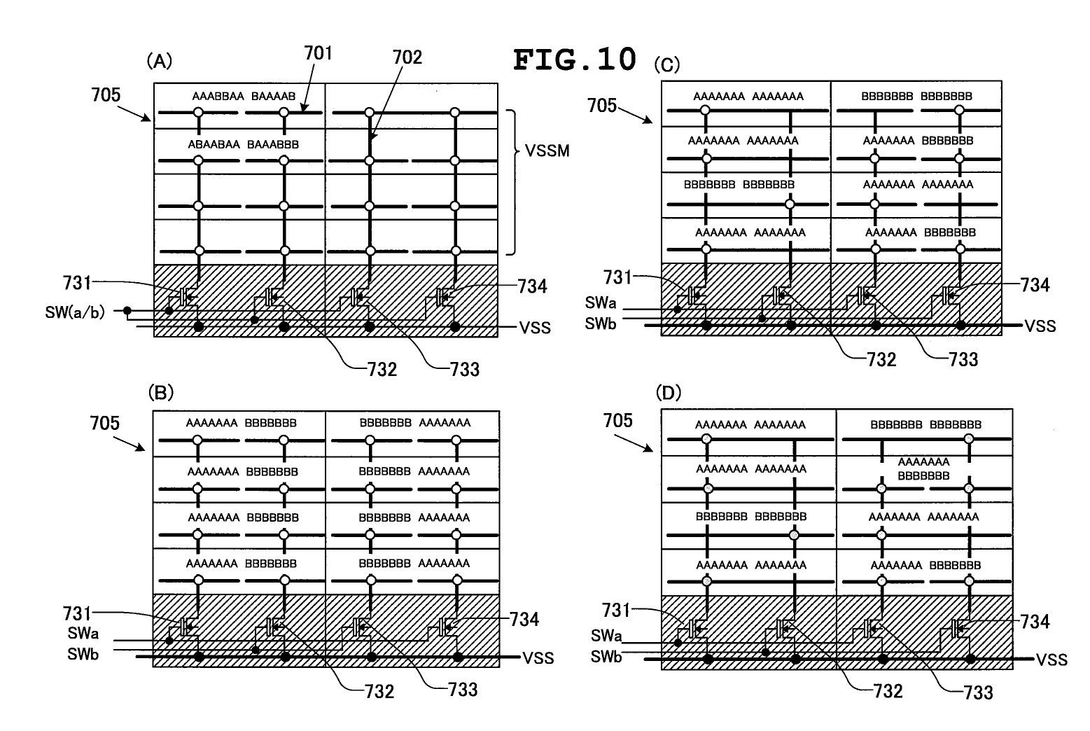

Here, it is desirable to adjust the gate sizes of the power switches depending on the circuit scales of the power shutdown groups A and B. All power switches 731, 732, 733 and 734 prior to relocation are set to standard sizes as shown in FIG. 10(A), for example. After the relocation, there are a case where power shutdown groups A and B are set equal in circuit scale as shown in FIG. 10(B) and a case where power shutdown groups A and B are different in circuit scale from one another as shown in FIG. 10(C). When the circuit scales of the power shutdown groups A and B are set equal as shown in FIG. 10(B), the sizes of the power switches 731, 732, 733 and 734 are the same as before the relocation. On the other hand, when the circuit scales of power shutdown groups A and B are different from one another by relocation as shown in FIG. 10(D), the power switches are changed in size. For instance, in the example shown in FIG. 10(D), the circuit scale of each power shutdown group A coupled to the power switch 731 is largest. The circuit scale decreases in order of the circuit scales of the power shutdown groups A and B coupled to the power switches 733 and 734, and the circuit scale of the power shutdown group B coupled to the power switch 732. Thus, MOS transistors each having a standard gate size are applied to the power switches 733 and 734, a MOS transistor larger in gate size than those of the power switches 733 and 734 is applied to the power switch 731, and a MOS transistor smaller in gate size than those of the power switches 733 and 734 is applied to the power switch 732. By doing so, the power switches are set to suitable ones depending on the sizes of the power shutdown groups A and B. Upon their setting, ones different in size and ones equal in size are embedded in advance and the sizes required therefor may be constructed.

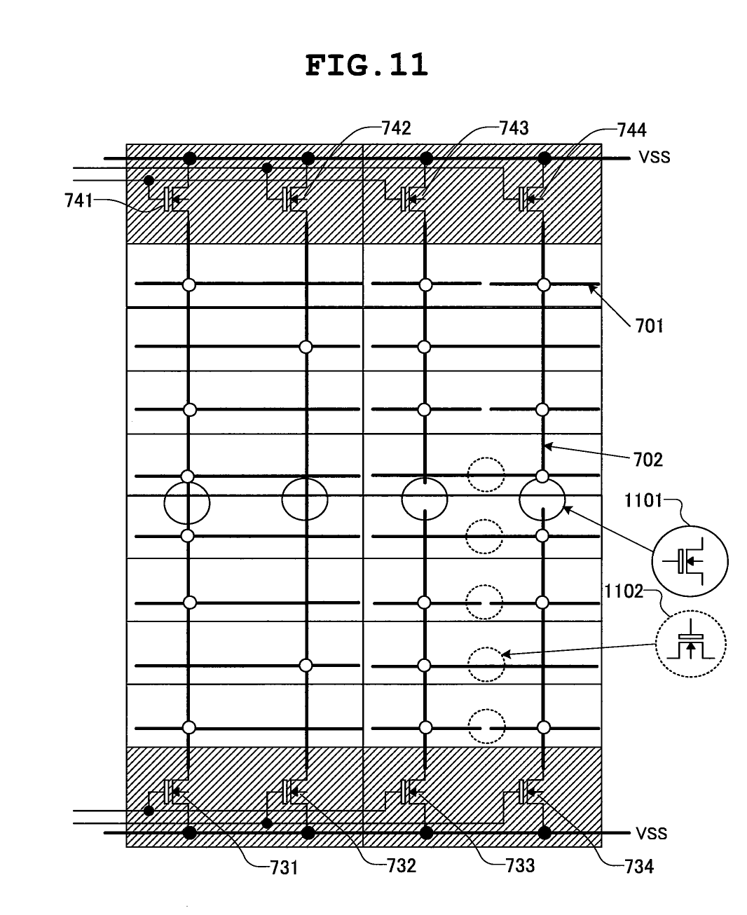

A further configuration example of the principal part of the semiconductor integrated circuit according to the present invention is shown in FIG. 11.

The semiconductor integrated circuit shown in FIG. 11 is much different from that shown in FIGS. 8 and 9 in that power switches 731 through 734 and 741 through 744 are provided at both ends of a plurality of metal upper layer lines 702 respectively. Metal lower wiring layer lines 701 and the metal upper layer lines 702 are suitably provided with cut portions respectively. They are cut into two by the cut portions. The cut portions can be formed by MOS transistors 1101 and 1102. The lines can be divided into two by bringing the MOS transistors to off states, respectively. Thus, since the power switches 731 through 734 and 741 through 744 are provided at both ends of the metal upper layer lines 702 respectively, the power switches 731 through 734 and their corresponding power switches 741 through 744 are connected in parallel, thereby reducing the combined on resistance value of the switches. Suitably providing the cut portions at the metal lower wiring layer lines 701 and the metal upper layer lines 702 and dividing the lines into the two by the cut portions respectively enable an increase in the number of power shutdown areas. For example, the metal upper layer line 702 is divided into two by the MOS transistor 1101, thereby enabling power shutdown of areas different from each other by means of the power switches 734 and 744.

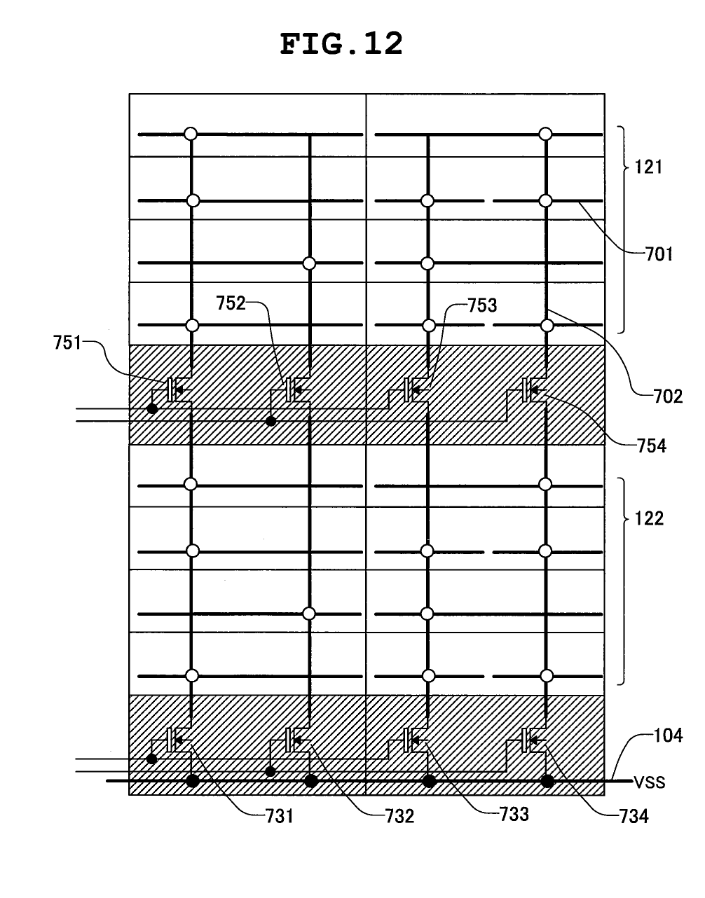

A still further configuration example of the principal part of the semiconductor integrated circuit according to the present invention is shown in FIG. 12.

The semiconductor integrated circuit shown in FIG. 12 is much different from that shown in FIG. 11 in that power switches 751 through 754 are provided at intermediate portions of a plurality of metal upper layer lines 702 respectively. Turning off power switches 731 through 734, for example enables power shutdown of areas 121 and 122. Turning off the power switches 751 through 754 enables power shutdown of the area 121.

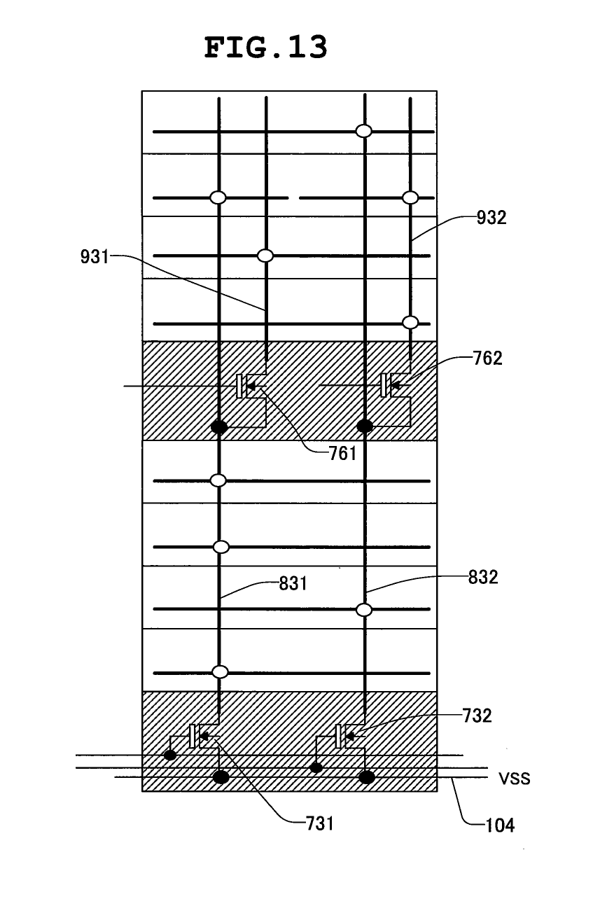

The power switches may be combined hierarchically. As shown in FIG. 13, for example, power switches 761 and 762 that belong to the low orders of power switches 731 and 732 are provided, and the power switches 761 and 762 are turned on to enable electric current to pass through lines 931 and 932 belonging to the low orders of metal upper layer lines 831 and 832. Combining the power switches hierarchically in this way enables an increase in the number of combinations of power shutdown areas.

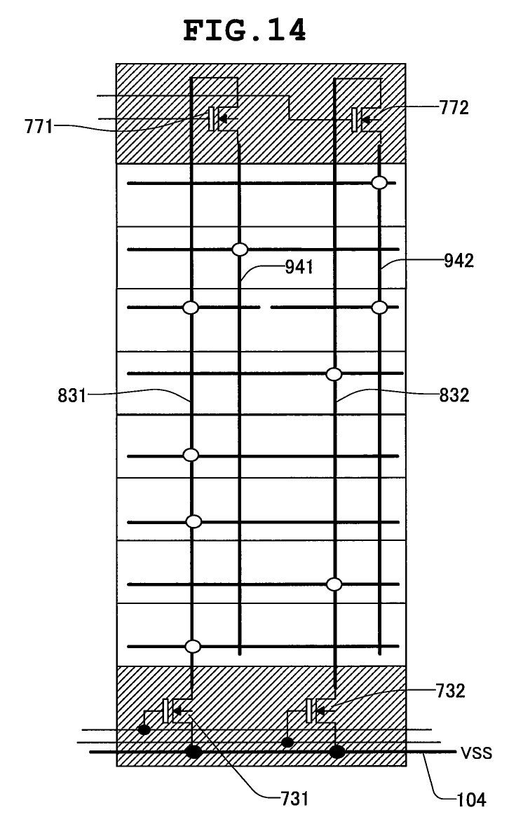

As shown in FIG. 14, power switches 731, 732, 771 and 772 are provided on both end sides of metal upper layer lines 831 and 832 respectively, and lines 941 and 942 are provided so as to fold back the metal upper layer lines 831 and 832. Since the supply of power to the lines 941 and 942 can be cut off by the power switches 771 and 772, adaptation to an increase in the number of power shutdown areas is enabled.

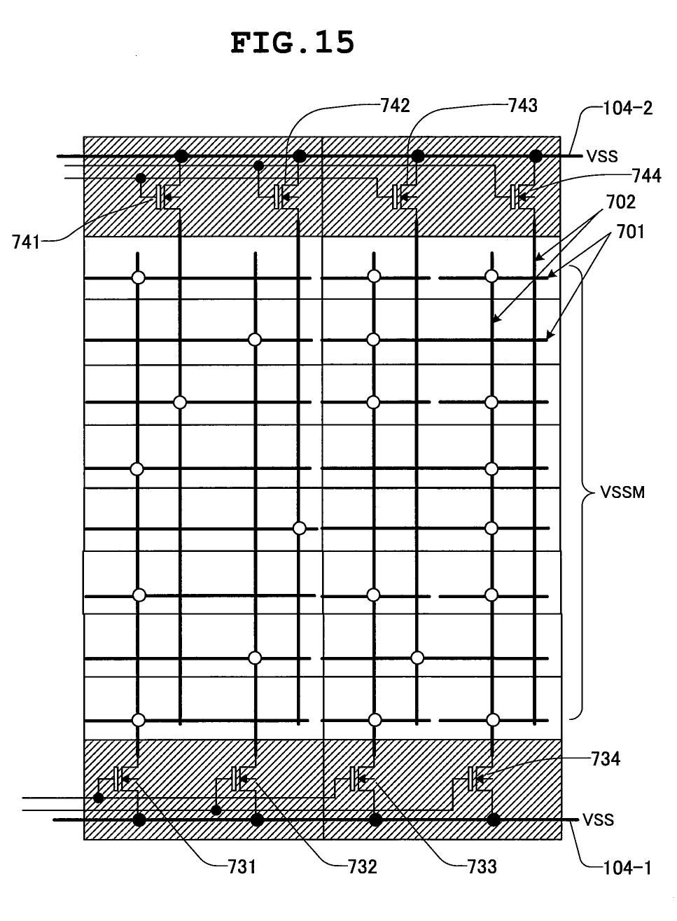

As shown in FIG. 15, a plurality of power switches 731 through 734 and 741 through 744 are provided on both end sides of a plurality of metal upper layer lines 702, and one ends of the metal upper layer lines 702 can be coupled to the power switches 731 through 734 and 741 through 744 alternately. The power switches 731 through 734 are coupled to a first low-potential side power VSS line 104-1. The power switches 741 through 744 are coupled to a first low-potential side power VSS line 104-2. Thus, the power switches 731 through 734 and 741 through 744 are capable of cutting off the supply of power to the metal upper layer lines 702 different from one another, based on control signals. This is adaptable to an increase in the number of power shutdown areas.

Although the above example has explained where the power switches for cutting off the supply of power to the power shutdown areas are provided on the first low-potential side power VSS sides, the power switches having the above functions can be provided on the high-potential side power VDD side. As shown in FIG. 16, for example, high-potential side power VDD side power switches 781 through 784 are provided along a high-potential side power VDD line 103, and low-potential side power VSS side power switches 731 through 734 are provided along a first low-potential side power VSS line 104. The high-potential side power VDD side power switches 781 through 784 are configured as p channel type MOS transistors. Source electrodes thereof are coupled to the high-potential side power VDD line 103, and drain electrodes thereof are coupled to their corresponding metal upper layer lines 702. The low-potential side power VSS side power switches 731 through 734 are configured as n channel type MOS transistors. Source electrodes thereof are coupled to the first low-potential side power VSS line 104, and drain electrodes thereof are coupled to their corresponding metal upper layer lines 702. Metal lower layer lines 701 are suitably divided corresponding to power shutdown areas and coupled to their corresponding metal upper layer lines 702 via contact holes. The low-potential side power VSS side power switches 731 and 733 are supplied with a control signal SW(a) for cutting off the supply of power to the power shutdown areas A. The low-potential side power VSS side power switches 732 and 734 are supplied with a control signal SW(b) for cutting off the supply of power to the power shutdown areas B. The high-potential side power VDD side power switches 782 and 784 are supplied with a control signal /SW(a) for cutting off the supply of power to the power shutdown areas A (where / means the inversion of logic). The high-potential side power VDD side power switches 781 and 783 are supplied with a control signal /SW(b) for cutting off the supply of power to the power shutdown areas B. Thus, even when the power switches are provided on the high-potential side power VDD side, adaptation to an increase in the power shutdown area is enabled in a manner similar to the above example.

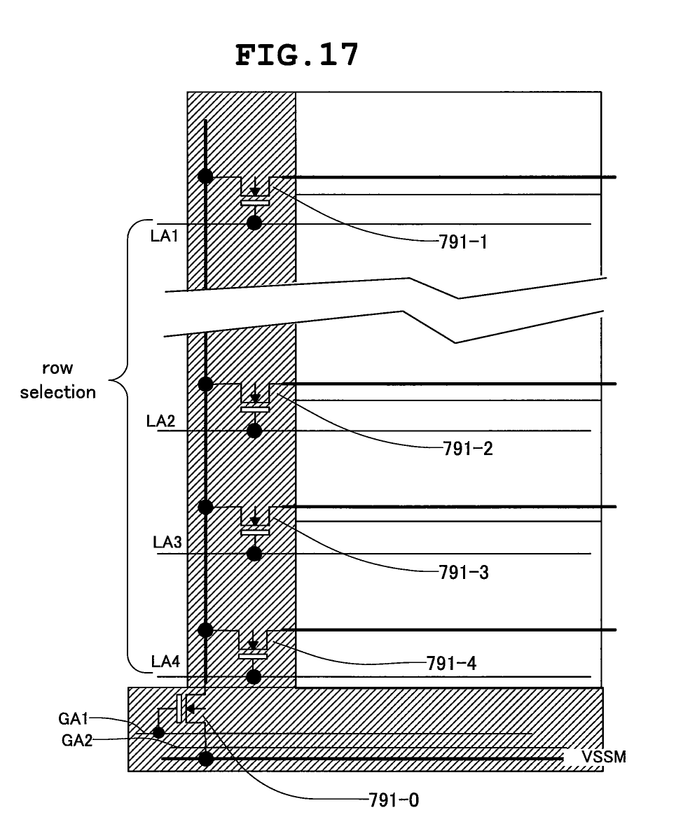

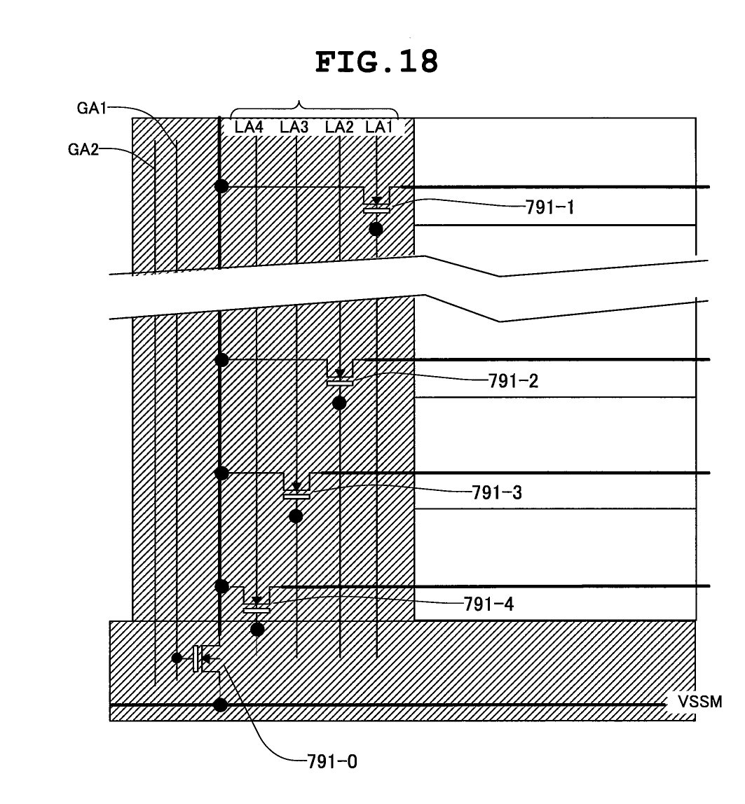

The power switches may be provided hierarchically with respect to second low-potential side power VSSM so as to cut off the supply of power to the power shutdown areas. A configuration example of such a case is shown in FIG. 17. Low-potential side power VSSM side power switches 791-1, 791-2, 791-3 and 791-4 are respectively provided as switches that belong to the low order of a second low-potential side power VSSM side power switch 791-0. The low-potential side power VSSM side power switch 791-0 is configured as an n channel type MOS transistor and supplied with a global control signal GA1 at its gate electrode. The low-potential side power VSSM side power switches 791-1, 791-2, 791-3 and 791-4 are respectively configured as n channel type MOS transistors and supplied with local control signals LA1, LA2, LA3 and LA4 for row selection at their gate electrodes. Thus, disposing the power switches hierarchically and executing the row selection by the control signals LA1, LA2, LA3 and LA4 make it possible to adapt to an increase in the number of the power shutdown areas.

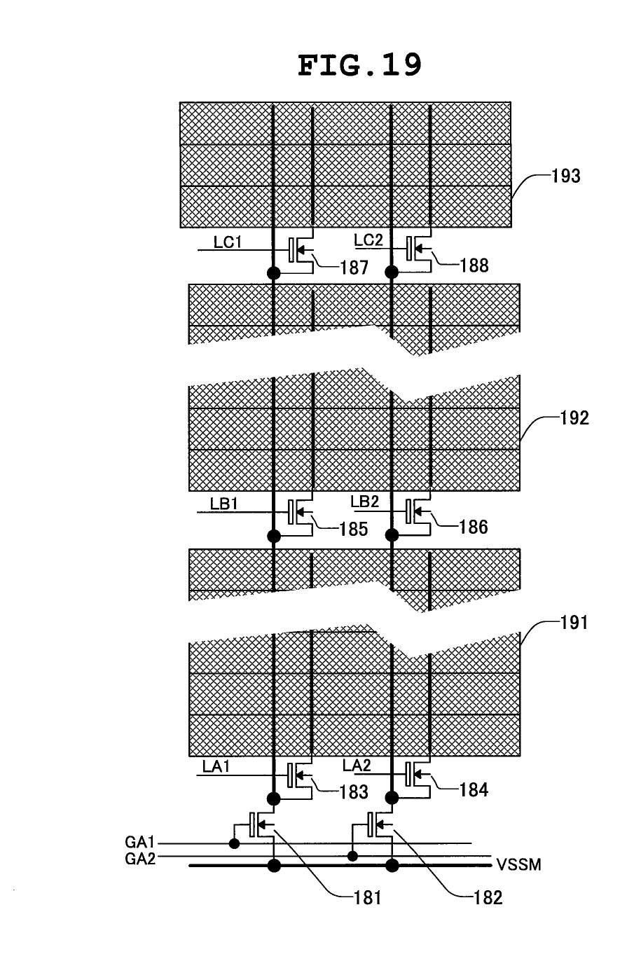

As shown in FIG. 19, second low-potential side power VSSM may be supplied to cell areas 191, 192 and 193 hierarchically. There are provided power switches 181 and 182 coupled to the second low-potential side power VSSM line. Power switches 183 through 188 are provided as switches that belong to the low orders of the power switches 181 and 182. Each of the power switches 183 through 188 enables power shutdown for each of the cell areas 191, 192 and 193.

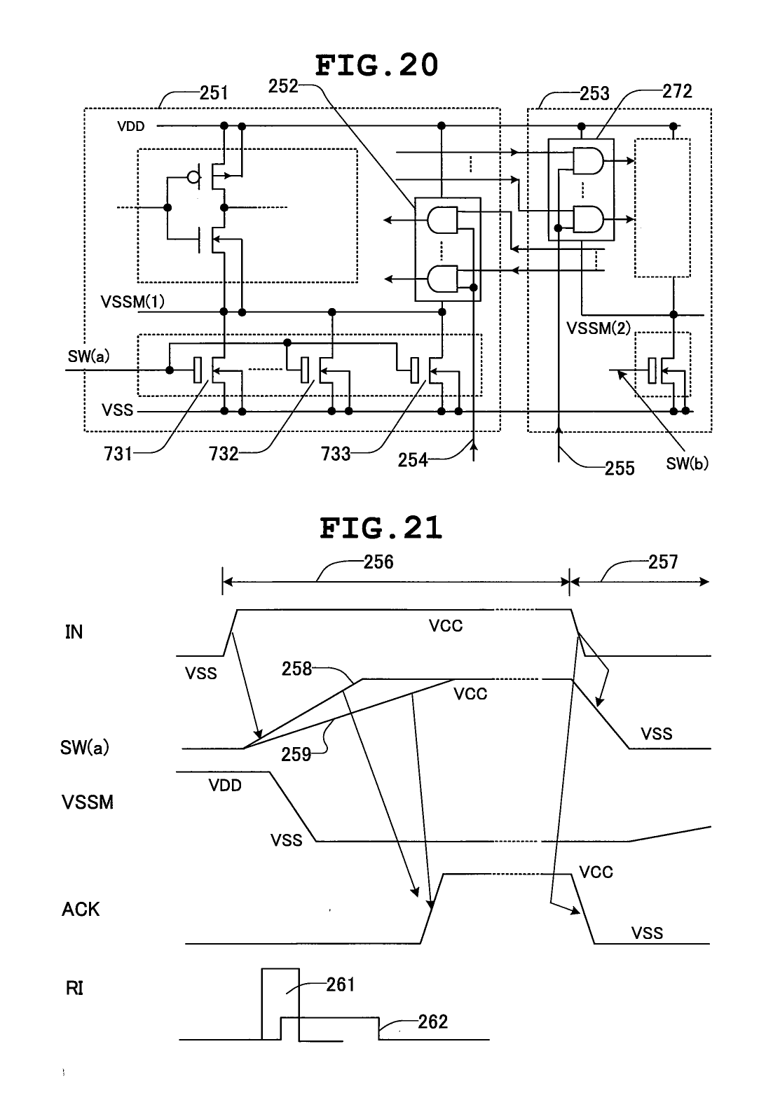

When such a circuit configuration that the transfer of signals between power shutdown areas 251 and 253 is taken as shown in FIG. 20, indefinite propagation preventing circuits 252 and 272 may be provided so as to avoid the occurrence of random or indefinite propagation of signals in one of the power shutdown areas 251 and 253 by virtue of power shutdown of the other thereof. Although not restricted in particular, the indefinite propagation preventing circuits 252 and 272 are constituted of two-input AND gates respectively. The signals transferred between the power shutdown areas 251 and 253 are inputted to one input terminals of the two-input AND gates. Control signals 254 and 255 are respectively transmitted to the other input terminals thereof. When the control signals 254 and 255 are respectively brought to a low level, the two-input AND gates are respectively kept in an inactive state, so that their output logics are fixed, thereby preventing indefinite propagation.

FIG. 21 shows operating timing of the principal part shown in FIG. 20.

Reference numeral 256 indicates a transition period from an off state of each power switch to an on state thereof, and reference numeral 257 indicates a transition period from the on state of the power switch to its off state. Control signals SW(a) and SW(b) for switch driving are generated based on an input signal IN. During the high-level period 256 of the input signal IN, power switches 731, 732 and 733 are respectively transitioned from an off state to an on state. When the power switches are large in gate size, the control signal SW(a) rises relatively gently as indicated by a curve 259, whereas when the gate sizes are small, the control signal SW(a) rises quickly as indicated by a curve 258. An acknowledge signal ACK is a signal for notifying to the outside that power shutdown control is being done. The acknowledge signal ACK is generated by a circuit (not shown) for generating each of the control signals SW(a) and SW(b). The inrush current RI of power flows greatly when the gate sizes of the power switches 731, 732 and 734 are small (refer to 261) as compared with the case in which they are large (refer to 262). Since power noise becomes large when the inrush current RI of power flows greatly, the gate sizes are decided within the allowable range of power noise. Through current can be suppressed even by constructing a relatively large mirror capacitance between the drain and gate of each power switch and slowly raising the gate of the power switch. Incidentally, a high voltage (VCC) is applied to the control signals SW(a) and SW(b) from the corresponding high-potential side power VDD. As a result, the on resistance of each power switch is easily reduced and a VDD operating margin of each core cell area is easily ensured.

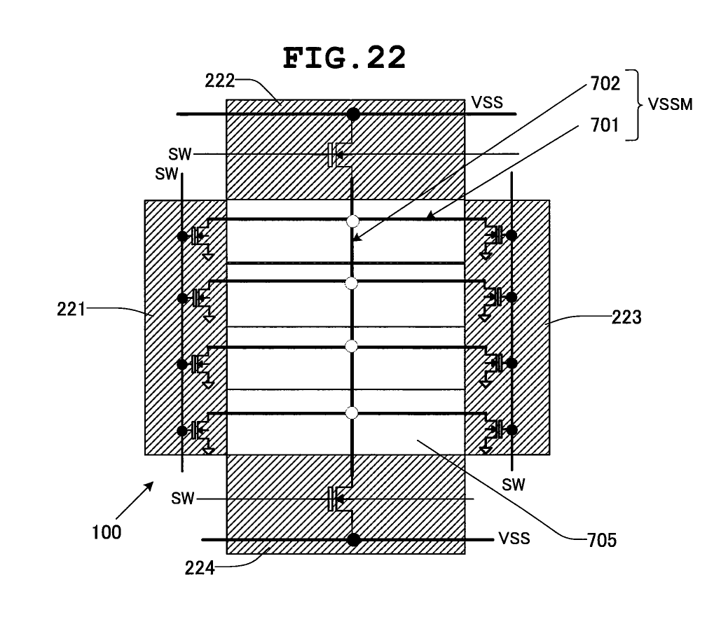

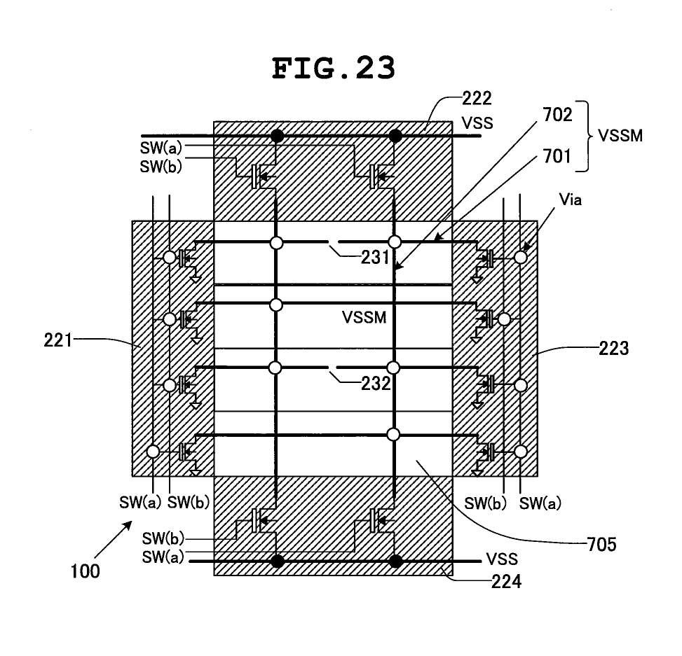

Still further configuration examples of the principal part of the semiconductor integrated circuit are shown in FIGS. 22 and 23.

As shown in FIGS. 22 and 23, power switch circuits 221, 222, 223 and 224 can be provided along the four peripheral portions of rectangular cell areas 705 respectively. In this case, metal lower layer lines 701 are coupled to the power switch circuits 221 and 223, and metal upper layer lines 702 are coupled to the power switch circuits 222 and 224. Thus, since the power switch circuits 221, 222, 223 and 224 are provided along the four peripheral portions of the cell areas 705, they enable the interruption of the supply of power to the cell areas 705, thus making it possible to reduce the combined resistance value of power supply paths and suppress a reduction in voltage level at power supply. Incidentally, cut portions 231 and 232 are provided at some of the metal lower layer lines 701 in FIG. 23 to divide the lines, thereby making it possible to adapt to an increase in the number of power shutdown areas.

While the invention made above by the present inventors has been described specifically on the basis of the embodiments, the present invention is not limited to the embodiments referred to above. It is needless to say that various changes can be made thereto within the scope not departing from the gist thereof.

### INDUSTRIAL APPLICABILITY

The present invention is widely applicable to semiconductor integrated circuits.

What is claimed is:

1. A semiconductor integrated circuit comprising:
cell areas each comprising a plurality of core cells arranged therein; and
power switches disposed corresponding to the respective cell areas,
wherein a plurality of power shutdown areas are respectively formed in units of the core cells, and
wherein, in the respective power shutdown areas, power shutdown is enabled by the power switches corresponding to the power shutdown areas.

2. The semiconductor integrated circuit according to claim 1, further including first low-potential side power lines each provided as a ground line, and
second low-potential side power lines coupled to the core cells respectively,
wherein the power switches are provided so as to be capable of interrupting the first low-potential side power lines and the second low-potential side power lines.

3. The semiconductor integrated circuit according to claim 2, wherein the power shutdown areas are formed by dividing the second low-potential side power lines.

4. The semiconductor integrated circuit according to claim 3, wherein the power switches are provided as MOS transistors whose gate sizes are determined depending upon the areas of the power shutdown areas corresponding to the power switches.

5. The semiconductor integrated circuit according to claim 4, further including comparison circuits for comparing identification information set in respective power shutdown area with comparison input information inputted thereto,
wherein the operation of each of the power switches is controlled based on the result of comparison by the comparison circuit.

6. A semiconductor integrated circuit comprising:
cell areas each comprising a plurality of core cells arranged therein;
power switches disposed corresponding to the respective cell areas;
metal upper layer lines respectively coupled to the power switches; and
metal lower layer lines which respectively intersect with the metal upper layer lines and are respectively coupled to the metal upper layer lines at points of intersection thereof,
wherein the cell areas are divided into a plurality of power shutdown areas in units of the core cells respectively,
wherein the metal lower layer lines are divided corresponding to the division of the power shutdown areas, and
wherein, in the respective power shutdown areas, power shutdown is enabled by the power switches corresponding to the power shutdown areas.

7. The semiconductor integrated circuit according to claim 6, further including first low-potential side power lines each provided as a ground line,
wherein the power switches include MOS transistors provided so as to be capable of interrupting the first low-potential side power lines and the metal upper layer lines.

8. The semiconductor integrated circuit according to claim 7, wherein the power switches include MOS transistors disposed on both end sides of the metal upper layer lines.

9. The semiconductor integrated circuit according to claim 8, wherein the power switches include first MOS transistors capable of electrically dividing the metal upper layer lines, and second MOS transistors capable of electrically dividing the metal lower layer lines.

10. The semiconductor integrated circuit according to claim 6, wherein the power switches include third MOS transistors respectively provided at one ends of the metal upper layer lines, and fourth MOS transistors respectively provided at intermediate portions of the metal upper layer lines.
